(19) United States
(12) Patent Application Publication
(10) Pub. No.: US 2020/0161167 A1
(43) Pub. Date: May 21, 2020

(54) SUBSTRATE HOLDING MEMBER AND SEMICONDUCTOR MANUFACTURING DEVICE

(71) Applicant: KYOCERA Corporation, kyoto-shi, Kyoto (JP)

(72) Inventors: Tetsuya INOUE, Omihachiman-shi, Shiga (JP); Masao YOSHIDA, Omihachiman-shi, Shiga (JP)

(21) Appl. No.: 16/633,090

(22) PCT Filed: Jul. 30, 2018
(86) PCT No.: PCT/JP2018/028483

§ 371 Date: Jan. 22, 2020

(30) Foreign Application Priority Data
Jul. 28, 2017 (JP) 2017-146661

(51) Int. Cl. H01L 21/687

(52) U.S. Cl. CPC H01L 21/68757

(57) ABSTRACT

A substrate holding member of the present disclosure includes a main body made of plate-shaped ceramics, and a coating film covering a surface of the main body, in which t1 is between 0.5 mm and 30 mm inclusive, t2 is between 3 μm and 0.1 t1 inclusive, and an F value represented by Formula 1 is 1×10²² or more, where K_{1C} denotes a fracture toughness, α1 denotes a thermal expansion coefficient, t1 denotes a thickness, and E1 denotes a Young's modulus of the ceramics, α2 denotes a thermal expansion coefficient, t2 denotes a thickness, E2 denotes a Young's modulus, and σ denotes a compressive strength of the coating film, and Sp denotes a safety factor of the substrate holding member. A semiconductor manufacturing device of the present disclosure includes the above-mentioned substrate holding member.

### TECHNICAL FIELD

The present invention relates to a substrate holding member used for holding a substrate in a semiconductor manufacturing device or the like.

### BACKGROUND ART

In a manufacturing process of a semiconductor element or a liquid crystal display device, an element or a circuit is formed on a substrate using semiconductor manufacturing devices such as an exposure device, a CVD device, and a dry etching device. In these devices, a cycle in which the substrate is carried into a processing section of the device, subjected to a desired process, and then carried out is repeated. Since the substrate is heated during the process, it is necessary to lower the temperature of the substrate to the heat resistance temperature or lower of a member that contacts and holds or carries the substrate (hereinafter, referred to as a substrate holding member) for carrying the substrate. The heat resistance of the substrate holding member thus affects cycle time. Patent Document 1 describes polytetrafluoroethylene (PTFE) as a resin for coating a ceramic member.

### RELATED ART DOCUMENT

### Patent Document

Patent Document 1: Japanese Unexamined Patent Publication No. 2000-183133

### SUMMARY OF THE INVENTION

A substrate holding member of the present disclosure includes a main body made of plate-shaped ceramics, and a coating film covering a surface of the main body, in which t1 is between 0.5 mm and 30 mm inclusive, t2 is between 3 μm and 0.1 t1 inclusive, and an F value represented by Formula 1 is 1×10²² or more, where K_{1C} denotes a fracture toughness, α1 denotes a thermal expansion coefficient, t1 denotes a thickness, and E1 denotes a Young's modulus of the ceramics, α2 denotes a thermal expansion coefficient, t2 denotes a thickness, E2 denotes a Young's modulus, and a denotes a compressive strength of the coating film, and Sp denotes a safety factor of the substrate holding member. A semiconductor manufacturing device of the present disclosure includes the above-mentioned substrate holding member.

### BRIEF DESCRIPTION OF THE DRAWINGS

FIG. 1 shows schematic views of a substrate holding member according to an embodiment of the present invention, where (a) is a top view and (b) is a cross-sectional view along A-A′.

FIG. 2 is a schematic view showing a model used for stress analysis.

FIG. 3 shows an example of the chemical structure of PI.

FIG. 4 shows the chemical structure of PBI.

### EMBODIMENTS FOR CARRYING OUT THE INVENTION

Hereinafter, embodiments of the present invention will be described.

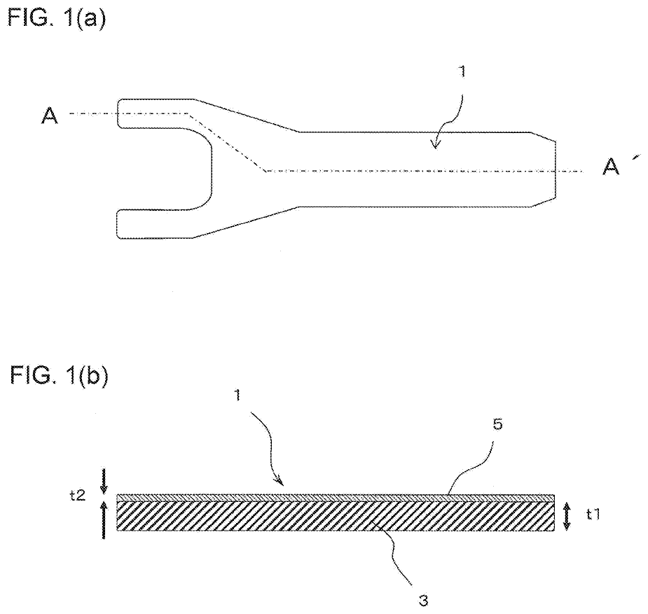

A substrate holding member is a member used for holding or carrying a substrate in a semiconductor manufacturing device. For example, the substrate holding member is a holding pin for holding a substrate in a processing chamber or a load lock chamber, or a carrying arm for carrying a substrate in a device. FIG. 1 shows schematic views of a substrate holding member 1 (carrying arm) according to an embodiment of the present invention.

The substrate holding member 1 of the present disclosure includes a main body 3 made of ceramics and a coating film 5 covering the surface of the main body 3. A thickness t1 of the main body 3 is in a range of 0.5 mm to 30 mm, a thickness t2 of the coating film 5 is in a range between 3 μm and 1/10 of the thickness t1 of the main body 3 inclusive.

The reason why the thickness of the main body 3 is set to 0.5 mm or more is that the mechanical strength and rigidity of the substrate holding member 1 can be maintained. The reason why the thickness t1 of the main body 3 is set to 30 mm or less is that the weight of the substrate holding member 1 can be relatively reduced.

The reason why the thickness t2 of the coating film 5 is set to 3 μm or more is that damage to the coating film 5 can be suppressed. The reason why the thickness t2 of the coating film 5 is set to 1/10 or less of the thickness t1 of the main body 3 is that an increase in the weight of the substrate holding member 1 can be suppressed.

Further, the substrate holding member 1 of the present disclosure has an F value of 1×10²² or more, the F value represented by Formula 1 where K_{1C} denotes a fracture toughness, α1 denotes a thermal expansion coefficient, t1 denotes a thickness, E1 denotes a Young's modulus, and m denotes a Weibull modulus of the ceramics, and α2 denotes a thermal expansion coefficient, t2 denotes a thickness, E2 denotes a Young's modulus, and σ denotes a compressive strength of the coating film 5. Note that the compressive strength of resin is the yield strength.

$$lnF = \frac{23}{m} {lnln ( - exp \{ - Γ ( 1 \text{/} {S}_{p} ) \} )}^{- 1} - 10 ln \{ {E}_{2} \times [ ( {t}_{1} - {t}_{2} ) \text{/} {t}_{2} ] \times [ 1 \text{/} ( {α}_{2} - {α}_{1} ) \text{/} {α}_{2} ] \} + ln ( 0.888 \times {10}^{8} \times \frac{1}{{K}_{1 C}^{23}} ) + 23 ln σ \qquad [ Formula 1 ]$$

An Sp value (also referred to as a safety factor) in Formula 1 is, as shown in Formula 2, the compressive strength σ of resin forming the coating film 5 divided by of calculated using NX (version 11.0.0.33) that is a stress analysis software using the finite element method from Siemens. This of is the maximum value when a generated stress is calculated using a model.

Sₚ=σ/σ_{f} [Formula 2]

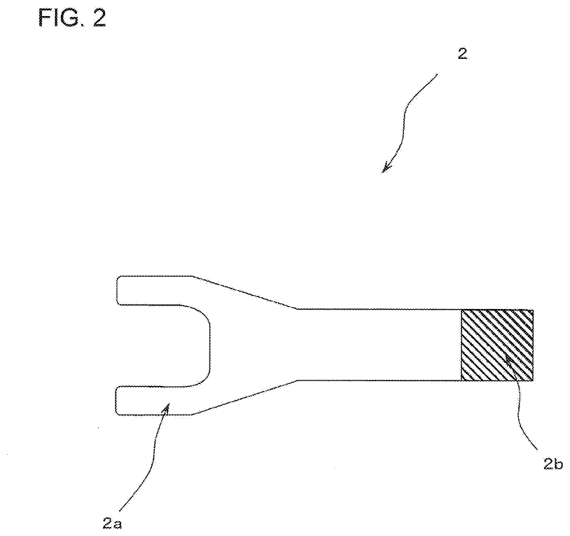

Using a model 2 having the shape shown in FIG. 2, of was calculated while the thicknesses of the main body 3 and the coating film 5 was changed. Respective values of the thermal expansion coefficients and the Young's moduli of the main body 3 and the coating film 5 were also changed.

The model 2 in FIG. 2 is a carrying arm 2. A substrate is placed on a substrate support portion 2a of the carrying arm 2 divided into two parts. The end portion opposite to the substrate support portion 2a is an attachment portion 2b at which the carrying arm 2 is attached to a substrate carrying device.

In the model 2 in FIG. 2, the coating film 5 covers the entire surface of one side of the main body 3. When the coating film 5 of the substrate support portion 2a in a range indicated by oblique lines in FIG. 2 was set to 300° C. and the attachment portion 2b in a range indicated by oblique lines was set to 20° C., of generated in the model 2 was calculated using NX.

For the NX settings, 3D tetrahedron was selected as the mesh type, and the element size of the mesh parameter was set to 4 mm. Try free-mapped mesh was also selected. The gravitational acceleration was set to 9.810 mm/sec². Enhancing resolution of polygonal geometry and connecting contact points were not used.

The Sp value was calculated by dividing the compressive strength of the resin forming the coating film 5 by of thus calculated. Further, the Sp value calculated using NX was substituted into Formula 1, and values of the thicknesses, the thermal expansion coefficients, and the Young's moduli of the main body 3 and the coating film 5 were also substituted. The fracture toughness for the main body 3 and the strength for the coating film 5 were also substituted.

A larger F value calculated from Formula 1 means a longer lifetime of the substrate holding member 1.

This formula 1 is based on prediction of a lifetime generated from a natural defect contained in the members of the substrate holding member 1, and is a numerical representation of effects of parameters on the durability of the substrate holding member 1. The parameters include dispersion of the natural defect existing in the substrate holding member 1 and the difference between the thermal expansion coefficients of the substrate holding member 1 and the coating film 5.

Note that, when the relation of Formula 1 is satisfied, the coating film 5 made of resin is first broken among the constituent elements of the substrate holding member 1. Accordingly, Formula 1 is obtained by excluding the strength of the ceramics that will not be broken for simplifying the formula. For the same reason, the Weibull modulus m of the ceramics was set to 15 for the calculation regardless of the type of the ceramics.

Each value relating to the ceramics to be substituted into Formula 1 is measured by the method shown in Table 1. In a simulation described later, values described in Table 1 were used for the values relating to the ceramics.

TABLE 1

| Items | Standards | Al₂O₃ | SiC | Si₃N₄ | Cordierite |
|---|---|---|---|---|---|
| Young's modulus | JIS R1602 | 370 | 440 | 300 | 140 |
| (E1):GPa | | | | | |
| Thermal expansion | JIS R1618 | 7.2 | 3.7 | 2.8 | 1.5 |
| coefficient | | | | | |
| (α1):1 × 10^{-6/}/° C. | | | | | |
| Fracture toughness | JIS R1607 | 4 | 2 | 7 | 1 |
| (K_{1C}):MPa · m^{0.5} | | | | | |

Each value relating to the resin to be substituted into Formula 1 is measured by the method shown in Table 2. In the simulation described later, the values described in Table 2 were used for the values relating to the resin forming the coating film 5. The Young's modulus of resin is a value calculated from the flexural modulus.

TABLE 2

| Items | Standards | PTFE | PI | PBI |
|---|---|---|---|---|
| Young's modulus (E2):GPa | ASTM D790 | 5 | 5 | 0.4 |
| Thermal expansion coefficient | ASTM D696 | 23 | 52 | 100 |
| (α 2):1 × 10^{-6/}/° C. | | | | |
| Compressive strength | ASTM D695 | 340 | 127 | 14 |
| (σ):MPa | | | | |

When obtaining the values to be substituted into Formula 1, in the case where test conditions such as a size specified in the measurement methods shown in Tables 1 and 2 are not satisfied, it is difficult to measure the values directly from the substrate holding member 1. In such a case, a test piece may be prepared separately from the substrate holding member 1 to be measured.

Data provided from a supplier of the ceramics or the resin may be used. Alternatively, for example, values described in Tables 1 and 2 may be used. For example, values described in the second edition of JIS Usage Series New Version of Plastic Material Selection Point issued by Japanese Standards Association may be used. When a material not described in these is used, data in Plastic Encyclopedia published by Asakura Publishing Co., Ltd. may be used.

The ceramics can be identified using, for example, XRD. The resin can be identified using, for example, infrared spectroscopy (IR), nuclear magnetic resonance (NMR), pyrolysis gas chromatography-mass spectrometry (Py-GC-MS), or the like.

The substrate holding member 1 of the present disclosure that satisfies Formula 1 has excellent durability.

Furthermore, it is preferably satisfied that the F value is 1×10³⁰ or more. Such a configuration makes the substrate holding member 1 have further excellent durability.

When a resin having a glass transition temperature of 270° C. or higher is used as the coating film 5, the substrate holding member 1 is excellent in heat resistance and can be used at high temperatures. Examples of the resin having a high glass transition temperature include polyimide (PI) and polybenzimidazole (PBI).

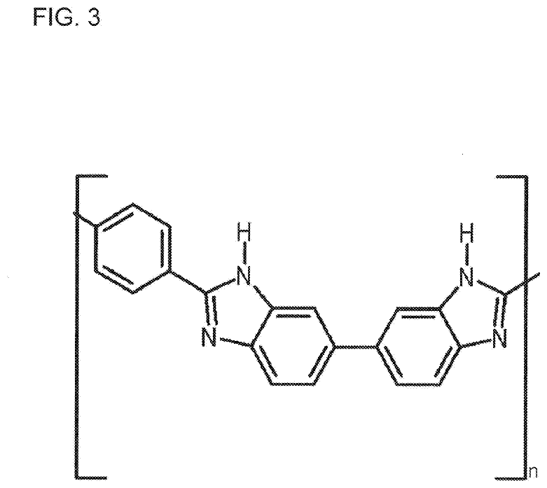

FIG. 3 shows the chemical structure of a typical PI. PI is a general term for polymers containing an imide bond in the repeating unit.

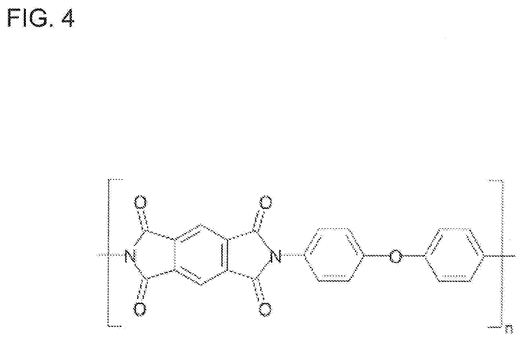

FIG. 4 shows the chemical structure of PBI. Benzimidazole is an organic compound represented by a molecular formula C₇H₆N₂, and is a heterocyclic compound in which a benzene ring and an imidazole ring are bonded together by sharing one side.

Since these resins are excellent in strength and heat resistance, the substrate holding member 1 is excellent in durability.

The heat resistance temperature (glass transition temperature) of PBI is about 427° C. and the heat resistance temperature of PI is about 285° C. to 410° C. They are higher than the heat resistance temperature of tetrafluoroethylene resin (PTFE) (about 260° C.). The heat resistance temperature of the PI having the structure shown in FIG. 3 is 410° C. Therefore, using PI as the resin allows for the usage even when the temperature of the substrate exceeds 260° C.

The tensile strength of PBI is about 160 MPa and the tensile strength of PI is about 86 MPa. They are higher than the tensile strength of PTFE (about 20 to 35 MPa). Therefore, even when the device vibrates, the resin hardly peels off at a contact portion between the substrate holding member 1 and the substrate.

Further, as the coating film 5, a resin having conductivity may be used. Using such a resin can suppress electrostatic breakdown of the substrate. Examples of the resin having conductivity include various resins to which a conductivity-imparting agent such as carbon or metal is added.

When imparting conductivity to the coating film 5, for example, metal powder or carbon powder may be added to the resin. In this case, each value of the major component of the resin excluding the metal powder or the carbon powder may be used as each value of the resin to be substituted into Formula 1. That is, when the resin is a matrix and the additive is dispersed in the matrix, the properties of the resin as the matrix are dominant, and thus influence on the calculation of the F value can be ignored.

It is preferable that the surface resistivity of the coating film 5 is between 10⁴ Ω/□ and 10¹⁰ Ω/□ inclusive. When the surface resistivity is in the above range, sparks are hardly generated and static electricity can be sufficiently removed. When having the thickness of 10 μm or more, the coating film 5 can easily cover the main body 3.

A conductivity-imparting additive (hereinafter, also referred to as an additive) is added to resin to impart conductivity to the resin. When the additive is an inorganic material such as carbon, metal, metal oxide, or metal salt, the conductivity can be easily adjusted, and deterioration and outgassing are reduced even when the temperature rises, as compared with organic materials. In particular, the additive itself having conductivity, such as carbon or metal, makes the conductivity higher. As the metal to be added, titanium, zinc, tin, alkali metal, alkaline earth metal, and alloys thereof are suitable. By adjusting the amount of the metal additive with respect to the total amount of the resin so that the surface resistivity of the coating film 5 is between 10⁴ Ω/□ and 10¹⁰ Ω/□ inclusive, the coating film 5 is able to remove static electricity.

The coating film 5 may cover the entire surface of the main body 3, or may be disposed at least on a part of the substrate support portion 2a. Further, when the coating film 5 is continuously disposed from the substrate support portion 2a to the attachment portion 2b and has conductivity, electrostatic breakdown of the substrate can be suppressed.

Various materials can be used as the ceramics constituting the main body 3. Examples include alumina ceramics (also represented as Al₂O), silicon carbide ceramics (also represented as SiC), cordierite ceramics (also represented as 2MgO.2Al₂O₃.5SiO₂ or CO), and silicon nitride ceramics (also represented as Si₃N₄). In particular, alumina ceramics, silicon carbide ceramics, or cordierite ceramics may be used. Using these ceramics makes the substrate holding member 1 excellent in durability.

Further, the ceramics may have conductivity for the same reason as the coating film 5.

Hereinafter, the simulation using Formula 1 will be described.

Each of Al₂O₃, SiC, Si₃N₄, and CO, as the ceramics, was combined with each of PTFE, PI, and PBI, as the resin. The relations with the durability of the substrate holding member 1 on the basis of the finite element method based on the respective properties described in Tables 1 and 2 were studied.

Tables 3 to 11 show the F value in Formula 1 when each of the ceramics in Table 1 was combined with each of the resins in Table 2, the thickness of the main body was changed in the range of 0.5 to 30 mm, and the thickness of the coating film 5 was changed in the range of 0.003 mm (3 μm) to 3 mm. Some combinations are omitted. In the tables, 1×10²² is represented as 1.0E+22.

TABLE 3

| | | t2 (mm) | | | | |
|---|---|---|---|---|---|---|
| Al₂O₃-PTFE | | 0.003 | 0.025 | 0.05 | 0.3 | 3 |
| t1 | 30 | 8.3E−17 | 1.4E−07 | 1.4E−04 | 9.2E+03 | 2.4E+14 |
| (mm) | 15 | 8.5E−14 | 1.4E−04 | 1.5E−01 | 1.0E+07 | |
| | 5 | 5.0E−09 | 8.5E+00 | 9.2E+03 | 9.3E+11 | |
| | 1.5 | 8.7E−04 | 1.6E+06 | 2.0E+09 | | |
| | 0.5 | 5.3E+01 | 1.4E+11 | 2.4E+14 | | |

As shown in Table 3, when PTFE was used as the resin and Al₂O₃ was used as the ceramics, the F value was less than 1×10²² for all combinations of t1 and t2. Similarly, when SiC, Si₃N₄, and CO were used as the ceramics and PTFE was used as the resin, the F value was less than 1×10²² for all combinations of t1 and t2. Thus, tables are omitted for the combinations other than Al₂O₃ and PTFE.

Hereinafter, one combination (frame) of t1 and t2 in the tables is expressed as one region.

Next, Tables 4 to 7 show the F value when PI was used as the resin and combined with the four types of ceramics.

TABLE 4

t2 (mm)

| Al₂O₃-PI | | 0.003 | 0.025 | 0.05 | 0.3 | 3 |
|---|---|---|---|---|---|---|
| t1 | 30 | 5.5E−04 | 8.9E+05 | 9.2E+08 | 6.0E+16 | 1.6E+27 |
| (mm) | 15 | 5.6E−01 | 9.2E+08 | 9.6E+11 | 6.8E+19 | |
| | 5 | 3.3E+04 | 5.6E+13 | 6.0E+16 | 6.1E+24 | |
| | 1.5 | 5.7E+09 | 1.1E+19 | 1.3E+22 | | |
| | 0.5 | 3.5E+14 | 8.9E+23 | 1.6E+27 | | |

TABLE 5

| | | t2 (mm) | | | | |
|---|---|---|---|---|---|---|
| SiC-PI | | 0.003 | 0.025 | 0.05 | 0.3 | 3 |
| t1 | 30 | 3.0E+04 | 4.8E+13 | 5.0E+16 | 3.3E+24 | 8.5E+34 |
| (mm) | 15 | 3.1E+07 | 5.0E+16 | 5.2E+19 | 3.7E+27 | |
| | 5 | 1.8E+12 | 3.1E+21 | 3.3E+24 | 3.3E+32 | |
| | 1.5 | 3.1E+17 | 5.8E+26 | 7.1E+29 | | |
| | 0.5 | 1.9E+22 | 4.8E+31 | 8.5E+34 | | |

TABLE 6

| | | t2 (mm) | | | | |
|---|---|---|---|---|---|---|
| Si₃N₄-PI | | 0.003 | 0.025 | 0.05 | 0.3 | 3 |
| t1 | 30 | 6.0E−10 | 9.8E−01 | 1.0E+03 | 6.6E+10 | 1.7E+21 |
| (mm) | 15 | 6.2E−07 | 1.0E+03 | 1.1E+06 | 7.5E+13 | |
| | 5 | 3.7E−02 | 6.2E+07 | 6.6E+10 | 6.7E+18 | |
| | 1.5 | 6.3E+03 | 1.2E+13 | 1.4E+16 | | |
| | 0.5 | 3.9E+08 | 9.8E+17 | 1.7E+21 | | |

TABLE 7

| | | t2 (mm) | | | | |
|---|---|---|---|---|---|---|
| CO-PI | | 0.003 | 0.025 | 0.05 | 0.3 | 3 |
| t1 | 30 | 2.0E+04 | 3.3E+13 | 3.4E+16 | 2.2E+24 | 5.8E+34 |
| (mm) | 15 | 2.1E+07 | 3.4E+16 | 3.6E+19 | 2.5E+27 | |
| | 5 | 1.2E+12 | 2.1E+21 | 2.2E+24 | 2.3E+32 | |
| | 1.5 | 2.1E+17 | 4.0E+26 | 4.8E+29 | | |
| | 0.5 | 1.3E+22 | 3.3E+31 | 5.8E+34 | | |

As shown in Table 4, when PI was used as the resin and Al₂O₃ was used as the ceramics, the F value was 1×10²² or more in five regions in the table. Note that the F value of 1×10²² or more is indicated in boldface in the table.

As shown in Table 5, when PI was used as the resin and SiC was used as the ceramics, the F value was 1×10²² or more in 10 regions in the table. As shown in Table 6, when PI was used as the resin and Si₃N₄ was used as the ceramics, there was no region having the F value of 1×10²² or more. As shown in Table 7, when PI was used as the resin and CO was used as the ceramics, the F value was 1×10²² or more in 10 regions in the table.

A combination having the F value of 1×10²² or more has durability superior to that of a conventionally used substrate holding member including ceramics covered with PTFE.

Considering the case of using PI as the resin and combining PI with the four types of ceramics, when PI is used as the resin, combining PI with Al₂O₃, SiC, or CO as the ceramics can yield the substrate holding member 1 with excellent durability.

Next, Tables 8 to 11 show the F value when PBI was used as the resin and combined with the four types of ceramics.

TABLE 8

| | | t2 (mm) | | | | |
|---|---|---|---|---|---|---|
| Al₂O₃-PBI | | 0.003 | 0.025 | 0.05 | 0.3 | 3 |
| t1 | 30 | 4.0E+18 | 6.6E+27 | 6.8E+30 | 4.5E+38 | 1.2E+49 |
| (mm) | 15 | 4.1E+21 | 6.8E+30 | 7.1E+33 | 5.0E+41 | |
| | 5 | 2.5E+26 | 4.1E+35 | 4.5E+38 | 4.5E+46 | |
| | 1.5 | 4.2E+31 | 7.9E+40 | 9.6E+43 | | |
| | 0.5 | 2.6E+36 | 6.6E+45 | 1.2E+49 | | |

TABLE 9

| | | t2 (mm) | | | | |
|---|---|---|---|---|---|---|
| SiC-PBI | | 0.003 | 0.025 | 0.05 | 0.3 | 3 |
| t1 | 30 | 1.8E+33 | 2.9E+42 | 3.0E+45 | 2.0E+53 | 5.1E+63 |
| (mm) | 15 | 1.8E+36 | 3.0E+45 | 3.1E+48 | 2.2E+56 | |
| | 5 | 1.1E+41 | 1.8E+50 | 2.0E+53 | 2.0E+61 | |
| | 1.5 | 1.9E+46 | 3.5E+55 | 4.3E+58 | | |
| | 0.5 | 1.2E+51 | 2.9E+60 | 5.1E+63 | | |

TABLE 10

| | | t2 (mm) | | | | |
|---|---|---|---|---|---|---|
| Si₃N₄-PBI | | 0.003 | 0.025 | 0.05 | 0.3 | 3 |
| t1 | 30 | 6.7E+09 | 1.1E+19 | 1.1E+22 | 7.3E+29 | 5.1E+63 |
| (mm) | 15 | 6.8E+12 | 1.1E+22 | 1.2E+25 | 8.3E+32 | |
| | 5 | 4.0E+17 | 6.8E+26 | 7.3E+29 | 7.5E+37 | |
| | 1.5 | 6.9E+22 | 1.3E+32 | 1.6E+35 | | |
| | 0.5 | 4.3E+27 | 1.1E+37 | 1.9E+40 | | |

TABLE 11

| | | t2 (mm) | | | | |
|---|---|---|---|---|---|---|
| CO-PBI | | 0.003 | 0.025 | 0.05 | 0.3 | 3 |
| t1 | 30 | 4.0E+32 | 6.6E+41 | 6.8E+44 | 4.5E+52 | 1.2E+63 |
| (mm) | 15 | 4.1E+35 | 6.8E+44 | 7.1E+47 | 5.1E+55 | |
| | 5 | 2.5E+40 | 4.1E+49 | 4.5E+52 | 4.5E+60 | |
| | 1.5 | 4.2E+45 | 7.9E+54 | 9.6E+57 | | |
| | 0.5 | 2.6E+50 | 6.6E+59 | 1.2E+63 | | |

As shown in Table 8, when PBI was used as the resin and Al₂O₃ was used as the ceramics, the F value was 1×10²² or more in 17 regions in the table. As shown in Table 9, when PBI was used as the resin and SiC was used as the ceramics, the F value was 1×10²² or more in all regions in the table. As shown in Table 10, when PBI was used as the resin and Si₃N₄ was used as the ceramics, the F value was 1×10²² or more in 15 regions in the table. As shown in Table 11, when PI was used as the resin and cordierite was used as the ceramics, the F value was 1×10²² or more in all regions in the table.

When PBI was used as the resin, the number of regions having the F value of 1×10²² or more increased as compared with the case of using PI.

As described above, it can be seen that using PI or PBI as the resin results in a widened range of combinations of the thicknesses of the main body 3 and the resin 5 that can improve the durability of the substrate holding member 1.

The substrate holding member 1 of the present disclosure can be used as a carrying arm. Using PBI or PI having excellent heat resistance as the resin allows for handling a substrate heated by various kinds of processing without waiting until the temperature of the substrate falls to room temperature. Therefore, cycle time can be shortened.

A semiconductor manufacturing device using the substrate holding member 1 has excellent durability.

The semiconductor manufacturing device is used in a manufacturing process of a semiconductor element or a liquid crystal display device. Examples of the semiconductor manufacturing device include an exposure device, a CVD device, and a dry etching device. In these devices, an element or a circuit is formed on a substrate by repeating a cycle in which the substrate is carried into a processing section of the device, subjected to a desired process, and then carried out. In the semiconductor manufacturing device, by connecting the coating film 5 to the ground electrically, the substrate holding member 1 is able to remove static electricity.

The embodiments of the present invention have been described above. However, the present invention is not limited to the above-mentioned embodiments and various modifications and improvements may be performed without departing from the scope of the present invention. For example, the coating film 5 does not have to cover the entire surface of the main body 3, and the thicknesses of the main body 3 and the coating film 5 may also be changed depending on a position. For example, the thicknesses of the main body 3 and the coating film 5 in the part that contacts a substrate in the substrate support portion 2a may be controlled to be within the range of the present disclosure. In a mode in which the thicknesses of the main body 3 and the coating film 5 are uneven, the thicknesses of the main body 3 and the coating film 5 in the part that contacts a substrate in the substrate support portion 2a may be used for the calculation using Formulas 1 and 2.

### DESCRIPTION OF THE REFERENCE NUMERAL

1: Substrate holding member

2: Model

2a: Substrate support portion

2b: Attachment portion

3: Main body

5: Coating film

1. A substrate holding member comprising:
a main body made of plate-shaped ceramics; and
a coating film covering a surface of the main body, wherein
t1 is between 0.5 mm and 30 mm inclusive,
t2 is between 3 μm and 0.1 t1 inclusive, and
an F value represented by Formula 1 is 1×10²² or more,
$$lnF = \frac{23}{m} {lnln ( - exp \{ - Γ ( 1 \text{/} {S}_{p} ) \} )}^{- 1} - 10 ln \{ {E}_{2} \times [ ( {t}_{1} - {t}_{2} ) \text{/} {t}_{2} ] \times [ 1 \text{/} ( {α}_{2} - {α}_{1} ) \text{/} {α}_{2} ] \} + ln ( 0.888 \times {10}^{8} \times \frac{1}{{K}_{1 C}^{23}} ) + 23 ln σ \qquad [ Formula 1 ]$$
where K_{1C} denotes a fracture toughness, α1 denotes a thermal expansion coefficient, t1 denotes a thickness, and E1 denotes a Young's modulus of the ceramics,
α2 denotes a thermal expansion coefficient, t2 denotes a thickness, E2 denotes a Young's modulus, and a denotes a compressive strength of the coating film, and
Sp denotes a safety factor of the substrate holding member.

2. The substrate holding member according to claim 1, wherein the F value is 1×10³⁰ or more.

3. The substrate holding member according to claim 1, wherein the coating film has a glass transition temperature of 270° C. or higher.

4. The substrate holding member according to claim 1, wherein the coating film is PBI or PI.

5. The substrate holding member according to claim 1, wherein the coating film has conductivity.

6. The substrate holding member according to claim 1, wherein the ceramics are any ceramics selected from alumina ceramics, silicon carbide ceramics, and cordierite ceramics.

7. The substrate holding member according to claim 1, wherein the ceramics have conductivity.

8. A semiconductor manufacturing device comprising the substrate holding member according to claim 1.
